(19) United States
(12) Patent Application Publication
(10) Pub. No.: US 2025/0240004 A1
(43) Pub. Date: Jul. 24, 2025

(54) A Method for Enhancing Controllability on Switching Speed of Electronic Cascode Power Device

(71) Applicant: The Hong Kong University of Science and Technology, Hong Kong (CN)

(72) Inventors: Jing CHEN, Hong Kong (CN); Ji SHU, Hong Kong (CN)

(21) Appl. No.: 19/008,638

(22) Filed: Jan. 3, 2025

Related U.S. Application Data
(60) Provisional application No. 63/622,579, filed on Jan. 19, 2024.

(51) Int. Cl. H03K 17/04

(52) U.S. Cl. CPC H03K 17/04

(57) ABSTRACT

A method for enhancing controllability on switching speed of an electronic cascode power device comprising a high-voltage normally-ON transistor having a drain connected to the high-side terminal of the cascode power device and a gate connected to the low-side terminal and a low-voltage normally-OFF transistor having a drain connected to a source of the high-voltage normally-ON transistor, a source connected to the low-side terminal of the cascode power device and a gate connected to the control terminal of the cascode power device; the method comprises introducing a coupling capacitor into the electronic cascode power device by: connecting a first terminal of the coupling capacitor to the source of the high-voltage normally-ON transistor; and connecting a second terminal of the coupling capacitor to the gate of the low-voltage normally-OFF transistor.

### CROSS-REFERENCE TO RELATED APPLICATIONS

The present application claims priority from the U.S. Provisional Patent Application No. 63/622,579 filed on 19 Jan. 2024, and the disclosure of which is incorporated herein by reference in its entirety.

### FIELD OF THE INVENTION

The invention is generally related to power electronic devices, specifically related to a method for enhancing controllability on switching speed of an electronic cascode power device.

### BACKGROUND OF THE INVENTION

The high-voltage (HV) cascode power devices use a low-voltage (LV) normally-OFF device (such as LV silicon (Si) metal-oxide-semiconductor field-effect transistor (MOSFET) or LV gallium nitride (GaN) high-electron-mobility transistor (HEMT)) to realize fail-safe normally-OFF gate control, and an HV normally-ON device (such as HV Silicon Carbide (SiC) junction-gate field-effect transistor (JFET) or HV GaN HEMT) to block the high voltage. Thanks to the superior device performance introduced by the cascode configuration, the cascode power devices have achieved successful commercialization with products available at 650-V and 1200-V voltage classes. Despite the successful market penetration, the cascode power devices are still facing a technical challenge, namely the weak switching speed control capability. During the switching process, the undesired voltage (or current) overshoot and oscillations may occur, and the switching speed of the power device can be tuned to suppress the overshoot and oscillations for the purpose of electromagnetic interference (EMI) management. For other power devices, such as SiC MOSFETs, the switching speed can be effectively controlled by simply adjusting the gate resistances. For cascode power devices, such a commonly employed method can no longer effectively control the switching speed.

Several solutions have been proposed to control the switching speed of cascode power devices. For a cascode power device having a SiC JFET as the HV normally-ON device and a Si MOSFET as the LV normally-OFF device, inserting additional diode(s) and resistors into the JFET's gate branch, as shown in FIG. 1, can tune the switching speed of the HV SiC JFET, so that the switching speed of the cascode power device can be controlled. However, the JFET's gate branch is not accessible for the cascode power devices in conventional packages. The other mainstream solution suggests driving the HV device and the LV device separately. Such a direct drive solution requires two control signals for a single cascode power device, making the control system and driver circuit more complicated. In addition, the large gate-drain capacitance of the HV SiC JFET can make the cascode power device switch very slow with the direct drive solution. Adding additional snubber circuits can also help reduce the switching speed of cascode power devices, so that the undesired oscillations and overshot can also be suppressed. However, in addition to the increased design complexity and cost, the turn-on and turn-off processes are slowed down simultaneously. This lack of freedom in separately optimizing the turn-on and turn-off processes can be limiting, as different switching speeds would be required to suppress the oscillations effectively during the turn-on and turn-off processes.

### SUMMARY OF THE INVENTION

One objective of the present invention is to provide a simplified and effective way to enhance controllability on switching speed of cascode power devices.

According to one aspect of the present invention, a method for enhancing controllability on switching speed of an electronic cascode power device is provided. The electronic cascode power device comprises a high-voltage normally-ON transistor having a drain connected to the high-side terminal of the cascode power device and a gate connected to the low-side terminal and a low-voltage normally-OFF transistor having a drain connected to a source of the high-voltage normally-ON transistor, a source connected to the low-side terminal of the cascode power device and a gate connected to the control terminal of the cascode power device. The method comprises introducing a coupling capacitor into the electronic cascode power device by: connecting a first terminal of the coupling capacitor to the source of the high-voltage normally-ON transistor; and connecting a second terminal of the coupling capacitor to the gate of the low-voltage normally-OFF transistor.

According to another aspect of the present invention, an electronic cascode power device with enhanced controllability on switching speed is provided. The cascode power device comprises: a high-voltage normally-ON transistor having a drain connected to a high-side terminal of the cascode power device and a gate connected to a low-side terminal of the cascode power device; a low-voltage normally-OFF transistor having a drain connected to a source of the high-voltage normally-ON transistor, a source connected to the low-side terminal of the cascode power device and a gate connected to a control terminal of the cascode power device; and a capacitor having a first terminal connected to the source of the high-voltage normally-ON transistor and a second terminal connected to the gate of the low-voltage normally-OFF transistor.

As the switching speed of the cascode power device is determined by the switching rate of these gate voltages, the coupling capacitor between the input control gate voltage (i.e. the gate voltage of the LV device) and the gate voltage of the HV device, which determines the switching speed of the cascode device. As such, the input control gate voltage gains enhanced control over the gate voltage of the HV device, leading to enhanced control over the switching speed of the cascode power device.

### BRIEF DESCRIPTION OF THE DRAWINGS

Embodiments of the invention are described in more details hereinafter with reference to the drawings, in which:

FIG. 1 shows a circuit schematic of a conventional electronic cascode power device;

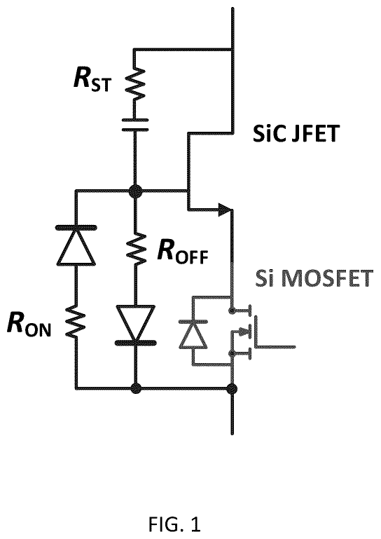

FIG. 2 shows a circuit block schematic of an electronic cascode power device in accordance with some embodiments of the present invention;

FIG. 3 shows a circuit diagram of an electronic cascode power device in accordance with a first embodiment of the present invention;

FIG. 4 shows a circuit diagram of an electronic cascode power device 100B in accordance with a second embodiment of the present invention;

FIG. 5 shows a circuit diagram of an electronic cascode power device 100C in accordance with a third embodiment of the present invention.

FIG. 6 shows the test set-up utilized to characterize the switching process of a device under test (DUT);

FIGS. 7A and 7B respectively show switching drain-source voltage of a conventional cascode power device and a single chip SiC MOSFET during switching process;

FIGS. 8A and 8B respectively show drain-source voltage and drain-source current of a cascode power device of the first embodiment of the present invention during switching process.

### DETAILED DESCRIPTION

In the following description, details of the present invention are set forth as preferred embodiments. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

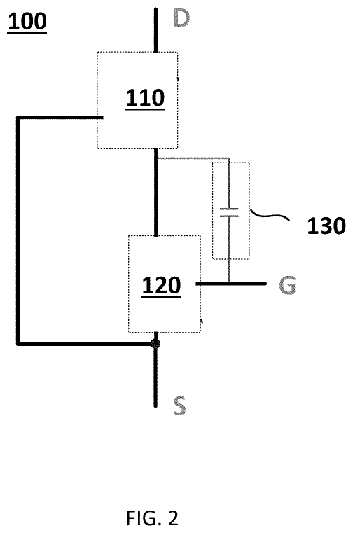

FIG. 2 shows a circuit block schematic of an electronic cascode power device 100 in accordance with some embodiments of the present invention. As shown, the electronic cascode power device 100 comprises a HV normally-ON transistor 110, a LV normally-OFF transistor 120 and a coupling capacitor 130. The electronic cascode power device 100 may have a device drain (or high-side terminal) D, a device source (or low-side terminal) S and a device gate (or control terminal) G.

The HV normally-ON transistor 110 is configured to have its drain connected to the high-side terminal D and its gate connected to the low-side terminal S. The LV normally-OFF transistor 120 is configured to have its drain connected to a source of the HV normally-ON transistor 110, a source connected to the low-side terminal S and a gate connected to the control terminal G.

The coupling capacitor 130 is configured to have its first terminal connected to the source of the HV normally-ON transistor 110 and a second terminal connected to the gate of the LV normally-OFF transistor 120.

The additional coupling capacitor 130 enhances the coupling between the gate terminal of the LV normally-OFF transistor 120 and the source terminal of the HV normally-ON transistor 110, thereby enhancing the coupling between the gate voltages of the HV normally-ON transistor 110 and the LV normally-OFF transistor 120. As a result, the input gate voltage of the LV normally-OFF transistor 120 gains enhanced control over the gate voltage of the HV normally-ON transistor 110, so that the switching speed of the cascode power device can be controlled.

The HV normally-ON transistor 110 may be selected from any one of, but not limited to, SiC JFET or GaN HEMT. The LV normally-OFF transistor 120 may be selected from any one of, but not limited to, GaN HEMT or Si MOSFET.

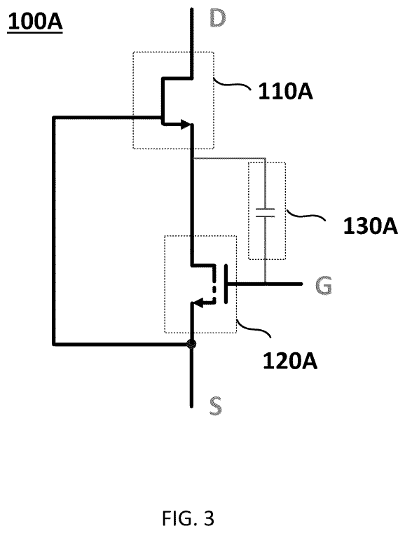

FIG. 3 shows a circuit diagram of an electronic cascode power device 100A in accordance with a first embodiment of the present invention. As shown, the electronic cascode power device 100A comprises a HV SiC normally-ON JFET 110A, a LV GaN normally-OFF HEMT 120A and a coupling capacitor 130A. The electronic cascode power device 100A may have a device drain (or high-side terminal) D, a device source (or low-side terminal) S and a device gate (or control terminal) G.

The HV SiC normally-ON JFET 110A is configured to have its drain connected to the high-side terminal D and its gate connected to the low-side terminal S. The LV GaN normally-OFF HEMT 120A is configured to have its drain connected to a source of the HV SiC normally-ON JFET 110A, a source connected to the low-side terminal S and a gate connected to the control terminal G.

The coupling capacitor 130A is configured to have its first terminal connected to the source of the HV SiC normally-ON JFET 110A and a second terminal connected to the gate of the LV GaN normally-OFF HEMT 120A. The coupling capacitor 130A has a capacitance value in a range of 1 to 2000 pF.

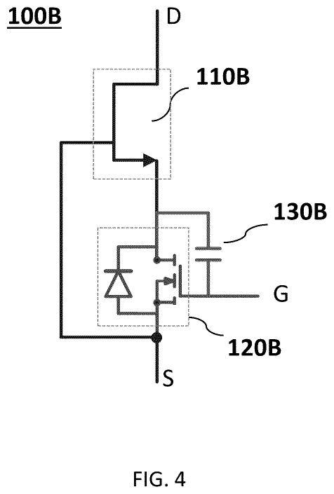

FIG. 4 shows a circuit diagram of an electronic cascode power device 100B in accordance with a second embodiment of the present invention. As shown, the electronic cascode power device 100B comprises a HV SiC normally-ON JFET 110B, a LV Si normally-OFF MOSFET 120B and a coupling capacitor 130B. The electronic cascode power device 100B may have a device drain (or high-side terminal) D, a device source (or low-side terminal) S and a device gate (or control terminal) G.

The HV SiC normally-ON JFET 110B is configured to have its drain connected to the high-side terminal D and its gate connected to the low-side terminal S. The LV Si normally-OFF MOSFET 120B is configured to have its drain connected to a source of the HV SiC normally-ON JFET 110B, a source connected to the low-side terminal S and a gate connected to the control terminal G.

The coupling capacitor 130B is configured to have its first terminal connected to the source of the HV SiC normally-ON JFET 110B and a second terminal connected to the gate of the LV Si normally-OFF MOSFET 120B. The coupling capacitor 130B has a capacitance value in a range of 1 to 2000 pF.

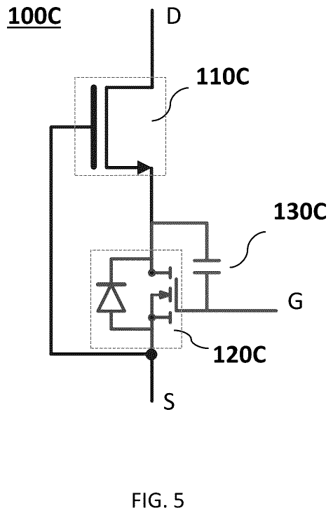

FIG. 5 shows a circuit diagram of an electronic cascode power device 100C in accordance with a third embodiment of the present invention. As shown, the electronic cascode power device 100C comprises a HV GaN normally-ON HEMT 110C, a LV Si normally-OFF MOSFET 120C and a coupling capacitor 130C. The electronic cascode power device 100C may have a device drain (or high-side terminal) D, a device source (or low-side terminal) S and a device gate (or control terminal) G.

The HV GaN normally-ON HEMT 110C is configured to have its drain connected to the high-side terminal D and its gate connected to the low-side terminal S. The LV Si normally-OFF MOSFET 120C is configured to have its drain connected to a source of the HV GaN normally-ON HEMT 110C, a source connected to the low-side terminal S and a gate connected to the control terminal G.

The coupling capacitor 130C is configured to have its first terminal connected to the source of the HV GaN normally-ON HEMT 110C and a second terminal connected to the gate of the LV Si normally-OFF MOSFET 120C. The coupling capacitor 130C has a capacitance value in a range of 1 to 2000 pF.

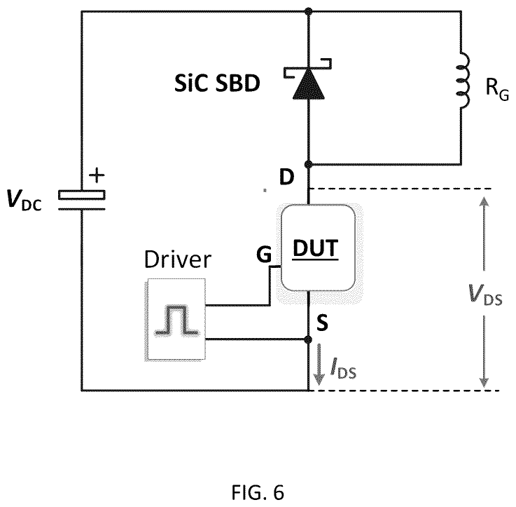

FIG. 6 shows the test set-up utilized to characterize the switching process of a device under test (DUT). The test set-up includes a driver, a DC voltage source, a SiC Schottky barrier diode (SBD) and a load RG. The driver is configured to apply a driving signal to the DUT through the gate G and source S of the DUT. The DC voltage source is configured to supply a DC voltage across the drain D and source S of the DUT. The SiC SBD and the load RG are connected in parallel, and between a positive terminal of the DC voltage source and the drain D of the DUT.

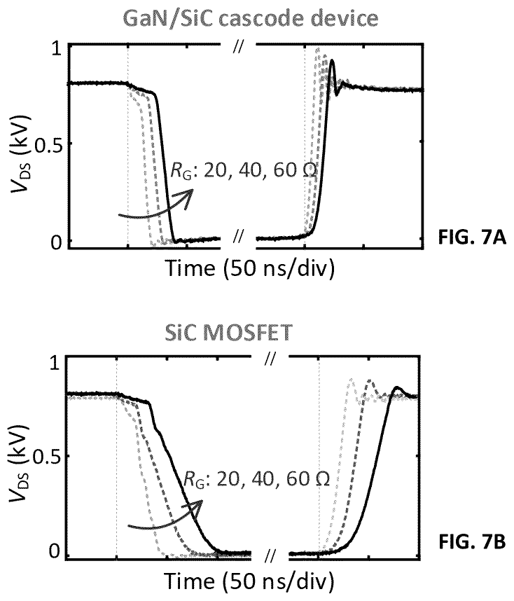

FIGS. 7A and 7B respectively show switching behaviors of drain-source voltage of a single-chip SiC MOSFET and a cascode power device without our proposed solution, that is, a cascode power device comprising an HV normally-ON SiC JFET and an LV normally-OFF GaN HEMT, but without a coupling capacitor connected between the source of the HV SiC normally-ON JFET and the gate of the LV GaN normally-OFF HEMT. Measurements are taken for loads RG equal to 20, 40, and 60 Ω respectively. At higher gate resistances, the switching speed is still fast with overshoot and oscillation, indicating the cascode power device has weak switching speed control capability. In comparison, the switching speed of a single-chip SiC MOSFET is much slower at higher gate resistances, indicating strong switching speed control capability.

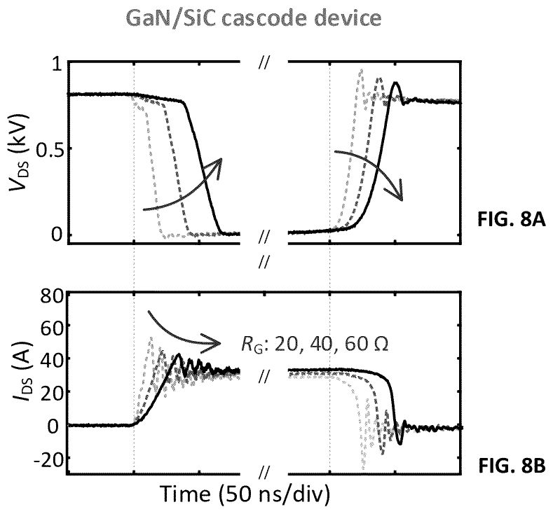

FIGS. 8A and 8B respectively show switching behaviors of drain-source voltage and drain-source current of a cascode power device of the first embodiment, that is, the cascode power device comprising an HV normally-ON SiC JFET, an LV normally-OFF GaN HEMT and a coupling capacitor connected between the source of the HV SiC normally-ON JFET and the gate of the LV GaN normally-OFF HEMT. The capacitance of the coupling capacitor is selected to be 150 pF. Measurements are taken for loads RG equal to 20, 40 and 60 Ω respectively. Compared with the results shown in FIGS. 7A and 7B, the obviously slower switching process and the suppressed oscillation at higher gate resistance indicate the strong switching speed control capability of the cascode power device.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A method for enhancing controllability on switching speed of an electronic cascode power device comprising a high-voltage normally-ON transistor having a drain connected to the high-side terminal of the cascode power device and a gate connected to the low-side terminal and a low-voltage normally-OFF transistor having a drain connected to a source of the high-voltage normally-ON transistor, a source connected to the low-side terminal of the cascode power device and a gate connected to the control terminal of the cascode power device; the method comprises introducing a coupling capacitor into the electronic cascode power device by:
connecting a first terminal of the coupling capacitor to the source of the high-voltage normally-ON transistor; and
connecting a second terminal of the coupling capacitor to the gate of the low-voltage normally-OFF transistor.

2. The method of claim 1, wherein the high-voltage normally-ON transistor is a SiC junction-gate field-effect transistor.

3. The method of claim 2, wherein the low-voltage normally-OFF transistor is a GaN high-electrol-mobility transistor.

4. The method of claim 2, wherein the low-voltage normally-OFF transistor is a Si metal-oxide-semiconductor field-effect transistor.

5. The method of claim 1, wherein the high-voltage normally-ON transistor is a GaN high-electrol-mobility transistor.

6. The method of claim 5, wherein the low-voltage normally-OFF transistor is a Si metal-oxide-semiconductor field-effect transistor.

7. The method of claim 1, wherein the low-voltage normally-OFF transistor is a GaN high-electrol-mobility transistor.

8. The method of claim 1, wherein the low-voltage normally-OFF transistor is a Si metal-oxide-semiconductor field-effect transistor.

9. The method of claim 1, wherein the coupling capacitor is a discrete component or monolithically integrated with the low-voltage normally-OFF transistor.

10. The method of claim 1, wherein the coupling capacitor has a capacitance value in a range of 1 to 2000 pF.

11. An electronic cascode power device with enhanced controllability on switching speed, comprising:
a high-voltage normally-ON transistor having a drain connected to the high-side terminal of the cascode power device and a gate connected to a low-side terminal of the cascode power device;
a low-voltage normally-OFF transistor having a drain connected to a source of the high-voltage normally-ON transistor, a source connected to the low-side terminal of the cascode power device and a gate connected to a control terminal of the cascode power device; and
a capacitor having a first terminal connected to the source of the high-voltage normally-ON transistor and a second terminal connected to the gate of the low-voltage normally-OFF transistor.

12. The electronic cascode power device of claim 11, wherein the high-voltage normally-ON transistor is a SiC junction-gate field-effect transistor.

13. The electronic cascode power device of claim 12, wherein the low-voltage normally-OFF transistor is a GaN high-electrol-mobility transistor.

14. The electronic cascode power device of claim 12, wherein the low-voltage normally-OFF transistor is a Si metal-oxide-semiconductor field-effect transistor.

15. The electronic cascode power device of claim 11, wherein the high-voltage normally-ON transistor is a GaN high-electrol-mobility transistor.

16. The electronic cascode power device of claim 15, wherein the low-voltage normally-OFF transistor is a Si metal-oxide-semiconductor field-effect transistor.

17. The electronic cascode power device of claim 11, wherein the low-voltage normally-OFF transistor is a GaN high-electrol-mobility transistor.

18. The electronic cascode power device of claim 11, wherein the low-voltage normally-OFF transistor is a Si metal-oxide-semiconductor field-effect transistor.

19. The electronic cascode power device of claim 11, wherein the coupling capacitor is a discrete component or monolithically integrated with the low-voltage normally-OFF transistor.

20. The electronic cascode power device of claim 11, wherein the coupling capacitor has a capacitance value in a range of 1 to 2000 pF.
